(19) United States
(12) Patent Application Publication
(10) Pub. No.: US 2011/0188543 A1
(43) Pub. Date: Aug. 4, 2011

(54) STATE SAVING CONTROL FOR GENERATING AT LEAST ONE OUTPUT SIGNAL

(75) Inventors: Remco Cornelis Herman Van de Beek, Eindhoven (NL); Jozef Reinerus Maria Bergervoet, Eindhoven (NL)

(73) Assignee: NXP B.V., Eindhoven (NL)

(21) Appl. No.: 13/057,433

(22) PCT Filed: Aug. 4, 2009
(86) PCT No.: PCT/IB2009/053375

§ 371 Date: Apr. 26, 2011

(30) Foreign Application Priority Data
Aug. 4, 2008 (EP) 08161723.5

(51) Int. Cl. H04B 1/713; G11C 7/00

(52) U.S. Cl. 375/135; 365/189.07; 375/E01.033

(57) ABSTRACT

The present invention proposes a control loop for receiving a reference signal r(t) and generating an output signal c(t) based on the reference signal r(t). The control loop comprises a subtracting element(320), a correcting element(330,350), a control path(340) and a storage element(360). The subtracting element(320) generates a difference signal d(t) including a difference between the reference signal r(t) and the output signal c(t). The correcting element (330,350) generates an adjusting signal b(t) based on the difference signal d(t). The control path(340) generates the output signal c(t) based on the adjusting signal b(t). And the storage element (360) stores at least one internal state of at least the correcting element(330,350) and applies the stored internal state to at least the correcting element(330,350) based on an instruction signal i(t).

### FIELD OF THE INVENTION

The invention relates to a control loop for generating an output signal based on a reference signal and an instruction signal, to a signal generator including the control loop, to a frequency hopping transceiver for transmitting and/or receiving a transmission signal and to a method performed in the control loop.

### BACKGROUND OF THE INVENTION

Signal generation apparatuses are widely used in telecommunication engineering for e.g. realizing so called frequency hopping. Frequency hopping is a frequency spreading method. Therein, the carrier frequency of a transmission signal is changed over the time. Such variable carrier frequencies are implemented in the physical protocol level of some wireless communication standards like Bluetooth.

Conventional signal generation apparatuses for generating variable carrier frequencies are phase-locked loops. Therein, a reference signal with a reference frequency is provided to the phase-locked loop, which generates an output signal having a multiple of the reference frequency. In other words, the phase-locked loop can change a carrier frequency by multiplying a reference frequency with different multiplication factors. These multiplication factors are usually provided to the phase-locked loop in an instruction signal.

However, frequency hopping may pose a challenge on the phase-locked loop of a transceiver. In some cases changing the carrier frequency needs to be done so fast that a single phase-locked loop multiplying a reference frequency with different multiplication factors is generally considered to be unusable, since the transition between the different frequencies, the so called hopping transient, endures too long. A good example, where such a single phase-locked loop is generally considered unusable would be WiMedia Ultra-Wide Band, where the hopping transient must be shorter than 9.5 ns. However, conventional phase-locked loops as described above have hopping transients in the order of at least hundreds of nanoseconds.

Several technical solutions exist to speed up the hopping transients. One common solution is to use some different forms of single-side-band mixing to generate carrier signals with different frequencies by changing multiplexers only. Another approach is to employ multiple phase-locked loops producing all possible output frequencies. Therein, one phase-locked loop is then selected by a multiplexer. A further solution is to use a ping-pong architecture, where two rather than one phase-locked loops are used in order to relax the lock time of the phase-locked loop from 9 ns to 312 ns in the case of WiMedia Ultra-Wide Band.

However, in all conventional solutions a single phase-locked loop is not sufficient to achieve a required fast hopping transient. The high hopping transients occur due to the high settling time in the phased-locked loop. The problem of the high settling time does not occur only in a phase-locked loop but in all control loops, that receive a reference signal and that are adapted to output a signal based on the reference signal. Since conventional solutions provide different control loops for different output signals to reduce the settling time and therewith the hopping transient, they are technically complex resulting in unnecessary space and power consumption. Further, different control loops unnecessarily increase production costs. A further subsidiary effect is the influence between the different control loops operating in the neighborhood amongst each other. This influence results into spurious tones reducing the quality of the output signal.

### OBJECT AND SUMMARY OF THE INVENTION

Therefore, it is an object of the present invention to provide a control loop requiring less space, production costs and electric power, and avoiding spurious tones.

The invention is based on the thought, that the object of the present invention can be solved by reducing the settling time of the control loop. Therein, the settling time is a time required by the control loop to switch from the internal state during outputting a first output signal to the internal state during outputting a second output signal. That is, by changing the output signal, the settling time occurs, since the internal state of the control loop does not change abruptly from outputting the first output signal to outputting the second output signal. Usually, the change of the internal state is a continuous procedure, that always requires the settling time. However, the settling time can be reduced by presetting the internal state of the correcting element in a control loop. This preset internal state avoids that the correcting element adjusts its internal state during the settling time. In other words, this preset internal state would greatly speed up the settling behavior of the control loop. It has been shown, that presetting the internal state of the correcting element could e.g. reduce the settling time and therewith the hopping transient in a phase-locked loop to less than 9 ns.

The present invention proposes two different approaches to preset the internal state of the correcting element. In a first approach, the control loop is instructed to fetch the internal state from a memory element at least when receiving the instruction to generate a predetermined signal. Therein, the control loop includes a plurality of different memory elements, wherein each memory element is adapted to store at least one operational state for the correcting element, which is required by the correcting element to output the respective predetermined signal with a reduced settling time. In other words, when the control loop receives an instruction to output a predetermined signal, the correcting element fetches an initial operational state from the memory element. Thus, the correcting element immediately switches into the required operational state and therewith immediately outputs the predetermined signal with a reduced settling time. In another approach, the present invention proposes to instruct the control loop to output a predetermined signal at a suitable point in time. This suitable point in time might be a moment at which the operational state of the correcting element during outputting a first predetermined signal is the same as required for outputting a second predetermined signal with a reduced settling time. In other words, the control loop is instructed to output the second predetermined signal by a suitable timing. The first and the second approach may also be combined to further reduce the settling time of the control loop.

According to the first approach, the present invention proposes a control loop for generating an output signal based on a reference signal. The control loop includes a subtracting element for generating a control difference between the reference and the output signal. This control difference is converted into an adjusting signal by a correcting element, wherein the adjusting signal is used to set a control path generating the output signal. The control loop further includes a storage element. This storage element stores a predetermined internal state at least of the correcting element. This stored internal state is used by the correcting element when outputting a predetermined signal. The storage element is controlled by an instruction signal which may be the same as the reference signal or a different signal. If the instruction signal indicates the output of the predetermined output signal, the storage element is adapted to apply the stored internal state to the correcting element, such that the operational state of the whole control loop is achieved immediately avoiding long settling times. That is, since the control loop according to the present invention can generate a correct output signal nearly immediately, there is no need to provide different control loops for different output signals, if very short settling times are required. Thus, apparatuses using the control loop according to the present invention require less space and less production costs.

Further, since such apparatuses use only one control loop, they require less electric power and avoid spurious tones.

Preferably, the control path is a controllable oscillator like a voltage controlled oscillator. Such oscillators are used in the fields of communication technology and especially in wireless communication devices using transmission signals having variable carrier frequencies. In these wireless communication devices, the carrier frequency hops between predetermined reference frequencies, wherein the transition between the reference frequencies must be as short as possible. Since the control loop according to the present invention has a very short settling time, the frequency hop between the different carrier frequencies is possible in a very short transition time with one single controllable oscillator.

Thus, a wireless communication device using the control loop according to the present invention can be assembled space-, energy- and cost-effective and produces less spurious tones.

The subtracting element may be a phase detector for detecting a phase difference between the reference signal and the output signal as control difference. Such a control loop is commonly known as phase-locked loop, since the control loop forms the output signal based on a phase difference between the reference and output signal and keeps the phase difference zero. The state in which the phase difference is zero is called phase lock. In other words, the settling time ends with the phase lock. Simulations and measurements have shown, that a phase-locked loop according to the present invention is able to reach the phase lock in less then 9 ns. This is a sufficient short settling time for wireless communication devices using transmission signals having variable carrier frequencies like Bluetooth communication devices and even WiMedia Ultra-Wide Band communication devices.

The correcting element may be adapted to integrate the control difference between the reference and output signal. Such a correcting element is called I-controller. By the I-controller, the control difference is zero in the steady state of the control loop. This results in a lower output signal of the subtracting element. By this means, the output signal of the subtracting element is less susceptible against spurious tones as e.g. due to pollution of the adjustment signal.

The correcting element may include a first integrator for integrating the control difference when the output signal should have a first shape and a second integrator for integrating the control difference when the output signal should have a second shape. This would be the most simple implementation of the present invention, since integrators can not only operate as correcting element in a control loop but also as state storage element. This means practically, that if the first integrator is constantly operating, it will constantly and intrinsically actualize its operational state by itself. In this time, the second integrator keeps its content unaltered. In case of changing the output signal and therewith selecting a new integrator for operation the currently operating first integrator will keep its actual operational state unaltered until the next selection for an operation. Thus, by using different integrators for different signal shapes, the correcting element is the currently operating integrator while the rest of the integrators are used as storage element. In case of changing the shape of the output signal, a respective integrator is chosen automatically having the correct internal state for further operation.

Another optional approach is to provide a plurality of different memory locations in the storage element, wherein the different storage elements are adapted to store different internal states of only one integrator. In that case, each memory location is provided for a different output signal shape and stores the most recent operational state of the integrator during the generation of the output signal with the respective shape. All other memory locations in the storage element maintain their content unaltered. In case of changing the output signal shape, the integrator stores its current internal state in a memory location corresponding to the current output signal shape and fetches its new internal state from a memory location corresponding to the changed output signal shape. The advantage of this solution is that the correction elements can be assembled with less integration elements saving space, costs and electric power.

The storage element may exemplary include capacitors, flip-flops or some other type of analog or digital memory. It is further possible to provide a hybrid storage element including a mixture of analogue and digital storage means.

The correcting element may further include a proportional gain element for amplifying the control difference, wherein the adjusting signal is a sum of the amplified control difference and the integrated control difference. The correcting element is therewith a PI-controller and can therefore stabilize the control loop by providing a certain damping.

The control loop may also include a frequency divider. This frequency divider may reduce the output frequency of the output signal prior providing to the subtracting element, preferably based on the instruction signal. Thus, the frequency can be controlled with simple and cost effective means. A phase-locked loop with such a frequency divider is called integer-PLL. Another or additional approach may be to reduce the frequency of the reference signal prior providing to the subtraction element by an alternative or further frequency divider. An integer-PLL further including a frequency divider for reducing the frequency of the reference signal is called fractional-PLL.

In the second approach according to the present invention, the control loop does not include a storage element but a clockable register for delaying the instruction signal preferably based on the reference signal. The clockable register guarantees, that the change between the different shapes of the output signal occurs at predetermined points in time. In the second approach the operational state of the subtracting element may be preset. For example, in a phase locked loop, the adjustment signal is generated based on a phase difference. In the steady state of the control loop the phase difference is zero. Thus, to reduce the settling time, the phase difference must be forced to zero as fast as possible. Based on the first approach according to the invention, this may be achieved by storing an operational state of the subtracting element. However, in case of the phase difference, this is technically very difficult and complex to realize. According to the second approach according to the invention, the start of the generation of the output signal will be delayed until a point in time, in which the phase difference is initially zero. A suitable criteria for this initial zero phase-difference may be a state of the reference signal. Thus, the instruction signal should be delayed until the reference signal has a suitable state, such that also the difference signal is kept zero from the start. Thus, the predetermined shape of the output signal may be immediately generated, such that the settling time of the control loop is reduced. In a preferred embodiment of the invention, the control loop according to the first embodiment and the control loop according to the second embodiment are combined.

Preferably, the instruction signal is output by the clockable register based on positive zero crossings of the reference signal. Such an embodiment is not only easy to realize, it has also the advantage, that the phase difference between the output signal and the reference signal can be kept zero by means of the clockable register. This is especially advantageous for the phase-locked loop, in which the phase difference is also the control difference.

The control loop may further include a delay element for timely delaying the reference signal prior providing to the subtracting element. This delay element would be an additional or alternative feature the clockable register, wherein the time delay may be derived from a delay between instructing a new shape for the output signal and the real effect within the control loop. As for example, the clockable register artificially generates a control difference between the output signal and the reference signal, since the instruction signal delayed by the clockable register becomes effective at the subtraction element after the artificial time delay forced by the above mentioned clockable register. The reference signal itself should therefore also be timely delayed prior supplying to the subtracting element by the same time interval delaying the effect of the instruction signal. Further or additional conditions for the time delay of the delay element may be a time delay occurring in the correction element, a time delay occurring in the control path and/or a time delay occurring in the feed-back of the output signal due to e.g. the frequency divider.

The present invention further proposes a signal generator including a control loop according to the present invention. Therein, the reference signal is a harmonic signal for setting a predetermined frequency of the output signal. As already mentioned, such signal generators may be widely used in the fields of electric engineering and especially in the fields of communication technology.

The present invention also proposes a frequency hopping transceiver for receiving and/or transmitting a transmission signal having a carrier frequency with a variable frequency. Such a transceiver may be used as Bluetooth transceiver and include a signal generator according to the present invention for generating a carrier signal with the carrier frequency of the transmission signal and a signal mixer for demodulating the transmission signal by mixing the carrier signal and the transmission signal. A frequency hopping receiver according to the present invention has a short frequency hopping transient time, wherein the signal generator is less complex, less power hungry and cheap, and generates less spurious tones.

The present invention further proposes a method for generating an output signal with a control loop according to the present invention. The method includes storing a predetermined internal state of at least the correcting element and applying the stored predetermined internal state to at least the correcting element based on receiving an instruction signal. This method achieves the same effects as achieved with the control loop according to the present invention.

### BRIEF DESCRIPTION OF THE DRAWINGS

The invention will be described in greater detail hereinafter, by way of non-limiting examples, with reference to the embodiments shown in the drawings.

FIG. 1 is a schematic view of a wireless communication system;

FIG. 2 is a diagram showing a frequency hopping of a carrier signal in a wireless communication system;

FIG. 3 is a schematic view of a signal generator including a control loop according to a first embodiment of the present invention;

FIG. 4 is a diagram showing signals in the control loop according to FIG. 3;

FIG. 5 is a schematic view of a signal generator including a control loop according to a second embodiment of the present invention; and

FIG. 6 is a diagram showing the delay between sending an instruction signal to and effecting the instruction signal in the control loop of FIG. 5.

### DESCRIPTION OF EMBODIMENTS

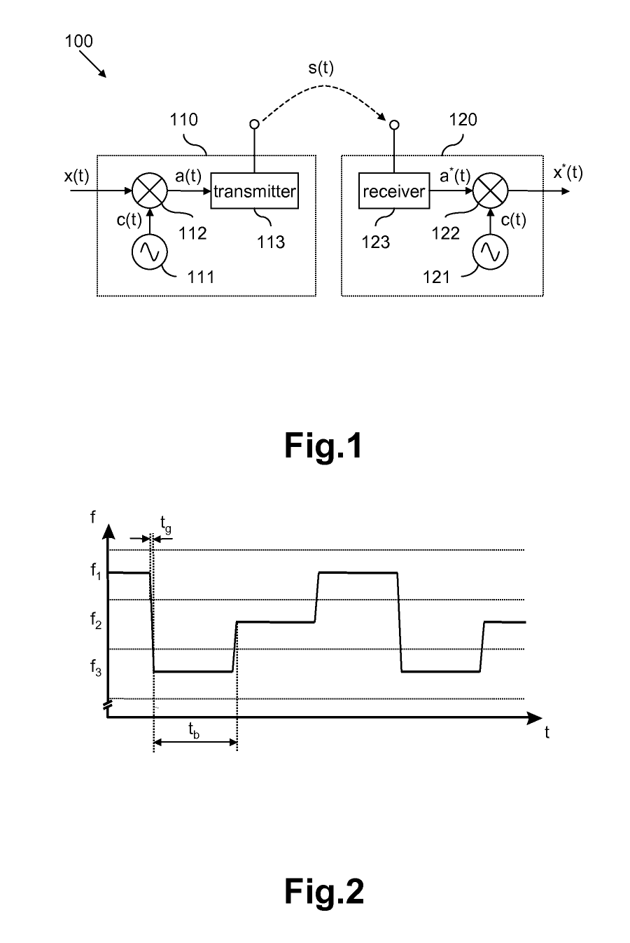

FIG. 1 is a schematic view of a wireless communication system 100. The wireless system comprises a transmitting system 110 receiving an information signal x(t) and transmitting the information signal x(t) in a transmission signal s(t), and a receiving system 120 receiving the transmission signal s(t) and extracting the information included in the transmission signal s(t) as received information signal x^{*}(t).

The transmitting system 110 includes a mixer 112 receiving the information signal x(t) and a carrier signal c(t) output by a signal generator 111 including a control loop according to the present invention. The mixer 112 multiplies the information signal x(t) and the carrier signal c(t) and outputs a modulated signal a(t). It should be understood, that the task of the mixer 112 is to modulate the information signal x(t) onto the carrier signal c(t). Thus, multiplying the carrier signal c(t) with the information signal x(t) as performed in amplitude modulation is only given as example. Other modulation methods as amending the frequency of the carrier signal c(t) based on the information signal x(t) like performed in frequency modulation, or amending the phase of the carrier signal c(t) based on the information signal x(t) as performed in phase modulation are also possible. The modulated signal a(t) is finally provided to a transmitter unit 113, which prepares the modulated signal a(t) for the wireless transmission by e.g. amplifying the modulated signal a(t) to a sufficiently high signal level, and which transmits the prepared modulated signal a(t) as transmission signal s(t) via an antenna to the receiving system 120.

The receiving system 120 includes a receiver unit 123, which receives the transmission signal s(t) via an antenna, and which prepares the transmission signal s(t) for further demodulation. The prepared transmission signal s(t) is output as the received modulated signal a^{*}(t) to a mixer 122, which multiplies the received modulated signal a^{*}(t) with the carrier signal c(t) output by a signal generator 121 having the same construction as the signal generator 111 in the transmitting system 110. Finally, the mixer 122 outputs the received information signal x^{*}(t). Likewise to the transmitting system 110, the task of the mixer 121 in the receiving system 120 is to demodulate the received modulated signal a^{*}(t) based on the carrier signal c(t). This task may be performed in a plurality of demodulation methods. This demodulation based on the carrier signal c(t) may be used, if the information signal x(t) is modulated by amplitude modulation. However, if the information signal x(t) is modulated by frequency modulation or phase modulation, the mixer 121 may read out the frequency information or the phase information of the received modulated signal a^{*}(t) by timely deriving the received modulated signal a^{*}(t).

As described, such wireless communication systems 100 wirelessly transmit the transmission signal s(t) including the information signal x(t) modulated into the carrier signal c(t). The information signal x(t) may include every suitable information in analogue or digital form. The transmission signal s(t) may be distorted on its way from the transmission system 110 to the receiving system 120. The distortion of the transmission signal s(t) leads to a loss of the information included in the information signal x(t). To avoid such a loss of information, modern transmission methods propose a lot of different signal securing mechanisms.

One of them is the so called channel coding, wherein predetermined information is included into the information signal x(t) at the transmission system 110. At the receiving system 120, it could be verified whether the predetermined information in the received information signal x^{*}(t) has been changed, indicating a distortion of the information included in the received information signal. In certain circumstances, the originally transmitted information may also be recovered based on the predetermined information included in the received information signal x^{*}(t). Principally, such channel coding methods may also be included into the communication system 100.

Another signal securing mechanism is based on the thought, that signal distortions depend on the carrier frequency f of the transmission signal s(t). In other word, different transmission signals s(t) with different carrier frequencies f will be distorted in different ways. This thought has been applied to a signal securing mechanism called frequency hopping. Therein, the frequency f of the carrier signal c(t) output by the signal generator 111 in the transmission system 110 is periodically changed over the time prior generating the modulated signal a(t). Accordingly at the receiving system 120, the frequency f of the carrier frequency c(t) output by the signal generator 121 must also be changed periodically in the same way as in the transmission system 110.

FIG. 2 shows an example for a periodical change of the frequency f of the carrier signal c(t) in the communication system 100.

Therein, the frequency f of the carrier signal c(t) starts at a first frequency f₁. At a predetermined point in time, the frequency f of the carrier signal c(t) hops from the first frequency f₁ to a third frequency f₃. This third frequency f₃ is kept for a predetermined time interval. Next, the frequency f hops from the third frequency f₃ to the second frequency f₂. Finally, the frequency f hops from the second frequency f₂ to the first frequency f₁ and the procedure restarts.

The time during which one of the frequencies f₁, f₂ or f₃ is constantly hold, is called symbol time t_{b}. In modern wireless communication systems the symbol time t_{b} endures between around 312.5 ns.

The time required to perform a frequency hop is called guard time t_{g}. Such a guard time t_{g} occurs due to a settling time required by a signal generator 111, 121 to set its new operational state for outputting the carrier frequency c(t) with the new frequency f. During the guard time t_{g} no information can be transmitted between the transmission system 110 and the receiving system 120. Thus, the guard time t_{g} reduces the time for transmitting information between transmission system 110 and the receiving system 120 and must therefore be kept as low as possible. Modern wireless communication systems have a guard time t_{g} under 9.5 ns. This reduction is mainly reached by using different signal generators for generating one carrier signal c(t) with different carrier frequencies f, such that the settling time in the overall signal generator is kept very low. However, the application of different signal generators suffers always a high consumption of power and space. Further, since more elements are required for producing such signal generators, the production costs increase. A final disadvantage is the generation of spurious tones occurring due to the signal coupling between the different signal generators.

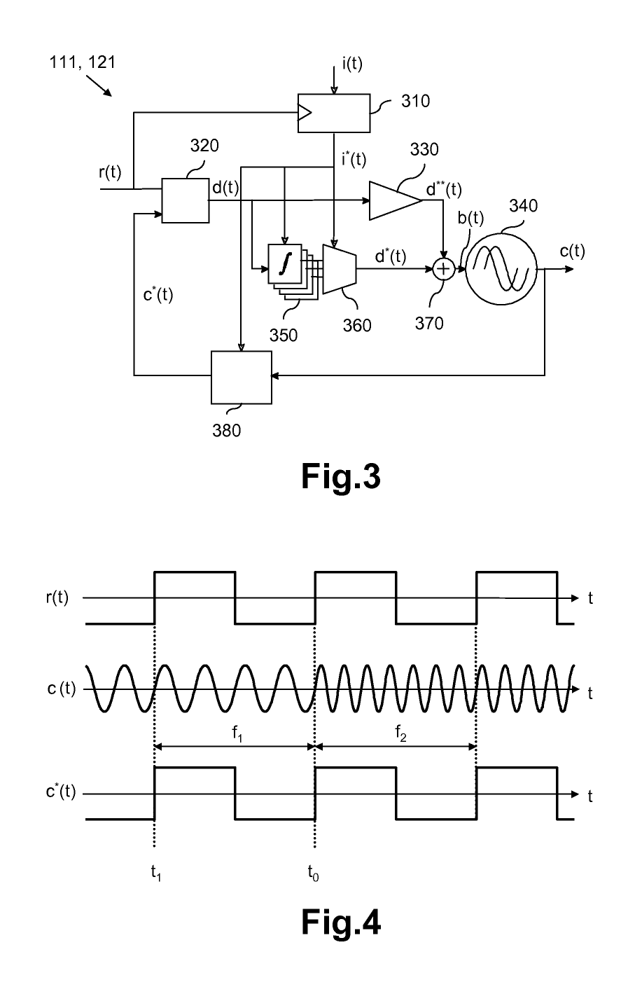

This problem can be avoided by a signal generator 111, 121 according to FIG. 3. The signal generator utilizes control loop being a phase-locked loop in the present embodiment.

The phase-locked loop includes a subtracting element, a correcting element, a control path and optionally a frequency divider, which are connected together in a loop. The phase-locked loop receives a reference signal r(t) via the subtracting element and outputs the carrier signal c(t). In common control loops, the reference signal r(t) is also known as command value. In the steady state of the phase-locked loop, that is if the frequency f of the carrier signal c(t) does not change anymore, the frequency f of the carrier signal c(t) can be derived from the frequency of the reference signal r(t) by a ratio N. This steady state is called phase-lock in the phase-locked loop.

In detail, the subtracting element is a phase detector 320 for detecting a phase difference d(t) between a reference signal r(t) and a normalized carrier signal c^{*}(t). In common control loops, this phase difference d(t) is also known as control difference.

The correcting element receive the phase difference d(t) and may include a proportional gain element 330 multiplying the phase difference d(t) with a predetermined factor for generating a multiplied phase difference d^{**}(t). Further, the correcting element may include a plurality of integrators 350, wherein one of the integrators 350 integrates the phase difference d(t) and generates an integrated phase difference d^{*}(t). The remaining integrators 350 keep their operational state unaltered and operate therefore as storage element. The multiplied phase difference d^{**}(t) and the integrated phase difference d^{*}(t) are summed together by a summing element 370 to form an adjusting signal b(t). Thus, in the present embodiment, the correcting element is a PI-control element, which has the advantage, that the phase difference d(t) of the phase-locked loop is zero in the phase-lock state.

The control path may be a controllable oscillator 340, preferably a voltage controllable oscillator. Based on the adjusting signal b(t), the controllable oscillator 340 outputs the carrier signal c(t) having a frequency f. The carrier signal c(t) can now be used in the wireless communication system 100 to modulate the information signal x(t) for a transmission between the transmission system 110 and the receiving system 120.

The carrier signal c(t) is fed back to the input of the phase-locked loop. Therein, the frequency f of the carrier signal c(t) may optionally be reduced by the optional frequency divider 380 according to the ratio N. Thus, the frequency divider 380 receives the carrier signal c(t) and outputs the normalized carrier signal c^{*}(t) having a frequency that is lower than the frequency f of the carrier signal c(t). In the phase-lock of the phase-locked loop the normalized carrier signal c^{*}(t) has the same frequency as the reference signal r(t). Thus, the phase difference d(t) between the reference signal r(t) and the normalized carrier signal c^{*}(t) is zero.

The integrators 350 are connected to a multiplexer 360 to choose the output of an currently operating integrator 350 according to an instruction signal i(t) being a delayed instruction signal i^{*}(t) as explained later. Further, the integrators 350 may also receive the delayed instruction signal i^{*}(t). By the delayed instruction signal i^{*}(t), one of the integrators 350 is selected for operation. Each of the integrators 350 may be selected for a predetermined frequency f of the carrier signal c(t). The currently operating integrator 350 changes its operational state for the integration. All other integrators keep their operational state unaltered and operate therefore as memory elements. If the delayed instruction signal i(t) indicates a change of the frequency f of the carrier signal c(t), the operation of the currently integrating integrator 350 is finished and a new integrator 350 is selected for operation. However, due to its intrinsic construction, the integrator 350 finishing its operation would not lose its last internal operational state but keep it unaltered until the next operation. In other words, by providing a plurality of different integrators 350, two different elements for the invention may be provided. On the one hand, the currently operating integrator 350 realizes the integration function of the correcting element. On the other hand, the integrators 350 keeping their content unaltered realizing the memory function, because these integrators 350 have the correct initial integration state when starting the next integration operation.

An alternative embodiment is not shown in FIG. 3. Therein, the operational state of only one integrator may be stored in different memory elements of a storage bank, wherein one memory element is provided for each frequency f of the carrier signal c(t). Each memory element stores at least the operational state of the only one integrator after finishing the integration for outputting the carrier signal c(t) with the respective frequency f. Further the one integrator takes its operational state from the respective memory element at the beginning of each integration operation.

Independently whether there are a plurality of different integrators 350 or only one integrator and different memory elements, the correct operational state of the integrating element of the correcting element is immediately available when starting the operation. This avoids the settling time in the integration element for a transition from an absolutely new initial state to the required operational state. Since the integration elements in the phase locked loop have the most influence on the overall settling time, the storing of the operational state of the integration elements noticeably reduces the settling time of the phase-locked loop and therewith the guard time t_{g} of the frequency f of the carrier signal c(t).

Thus, the memory elements may be capacitors for storing information in an analog way or flip-flops or some other form of digital memory for storing information in a digital way. It is also possible to combine different types of memory elements to provide a hybrid storage bank.

As already mentioned, the frequency divider 380 is an optional add-on in the phase-locked loop. If used, the delayed instruction signal i^{*}(t) may be used to also provide the ratio N for reducing the frequency f of the carrier signal c(t) to the frequency divider 380.

Summarized, the basic principle of the present invention is to store an operational state of a correcting element (which are integrators 350 in the present embodiment) of a control loop after operation in a memory element and to restore the operational state of the correcting element based in the content of the memory element prior a new operation. This avoids long settling times of the overall control loop. As shown, it is not compulsory to store the operational state of all elements in the correcting element, but only the operational state of these, which have the most important influence on the settling time. These are the integrators 350 in the present embodiment.

A further improvement of the present invention is the timing of the restoration of the operational state of the control element. That is, the further improvement relates to the timing of the frequency change of the carrier signal c(t). The timing is based on the thought, that a phase-locked loop is not directly controlled by the digital or analog value of the adjusting signal b(t) outputted by the controlling element but by the phase of the oscillator 340. Thus, the phase of the oscillator 340 is the final state variable for controlling the frequency of the oscillators 340. However, the phase of the oscillator 340 is technically difficult to store in a memory element. A technically more simple solution is to control the time of the frequency change of the oscillator 340 at suitable points in time. In other word, it is proposed to provide the instruction signal i(t) instructing the frequency change of the oscillator at suitable points in time. Since the instruction signal i(t) is provided always at a predetermined point in time, there is no need to store the phase of the oscillator 340 in a memory element, since the phase of the oscillator is known. In other words, this solution enables to directly control the final state variable of the phase locked loop. Thus, a full control of all internal states of the phase-locked loop is possible and therewith a fast re-lock to the new frequency. The timing should be discussed in further detail based on FIGS. 3 and 4.

In the preferred embodiment, the frequency change is controlled by controlling the ratio N in the frequency divider 380. The frequency divider 380 may preferably be a programmable divider 380. Therein, as shown in FIG. 4, when generating a carrier signal c(t) having first frequency f₁ as output prior the time point t₀, the programmable divider 380 reduces the frequency f₁ of the carrier signal c(t) according to a ratio N=4 when feeding back to the phase detector 320. Somewhere between the time points t₀ and t₁, the frequency f of the carrier signal c(t) should be changed from the first frequency f₁ to a second frequency f₂. As can be seen from FIG. 4, in case of the second frequency f₂, the programmable divider 380 reduces the frequency f of the carrier signal c(t) according to a ratio N=7.

As explained above, since the adjustment signal b(t) effecting a frequency change at the oscillator 340 is not the state variable directly controlling the frequency f of the oscillator 340, there is a risk, that in case of an abrupt change of the carrier signal c(t) the phase lock with the reference signal r(t) gets lost if the frequency change of the oscillator 340 is performed at an arbitrary point in time t. To avoid this loss of phase lock, it is proposed to directly store the phase of the oscillator 340. However, since this direct storage is technically very difficult to realize, this storage of the oscillators phase may be achieved, when the frequency f of the carrier signal c(t) changes in suitable signal states. Then, the phase of the oscillator 340 is know and needs not to be fetched from a memory element. The most easiest procedure is to force the signal change at the zero crossings of the carrier signal c(t).

It has been shown, that the best possibility is given, if the signal change is performed together with one of the positive zero crossings of the carrier signal c(t). The great advantage is, that a positive zero crossing occurs at the end of an interval of the reference signal r(t). In other words, it must be guaranteed only, that an instruction for changing the frequency t of the carrier signal c(t), namely the instruction signal i(t), is provided to the phase-locked loop at the end of an interval of the reference signal r(t). This can be suitably achieved by utilizing a clockable register 310, which receives the instruction signal i(t) and outputs the delayed instruction signal i(t) based on a positive edge of the reference signal r(t).

By this, it is guaranteed, that a frequency change of the carrier signal c(t) always occurs with positive zero crossings of the carrier signal c(t). Thus, the phase of the oscillator 340 is known in case of a frequency change and needs not to be fetched from a memory element.

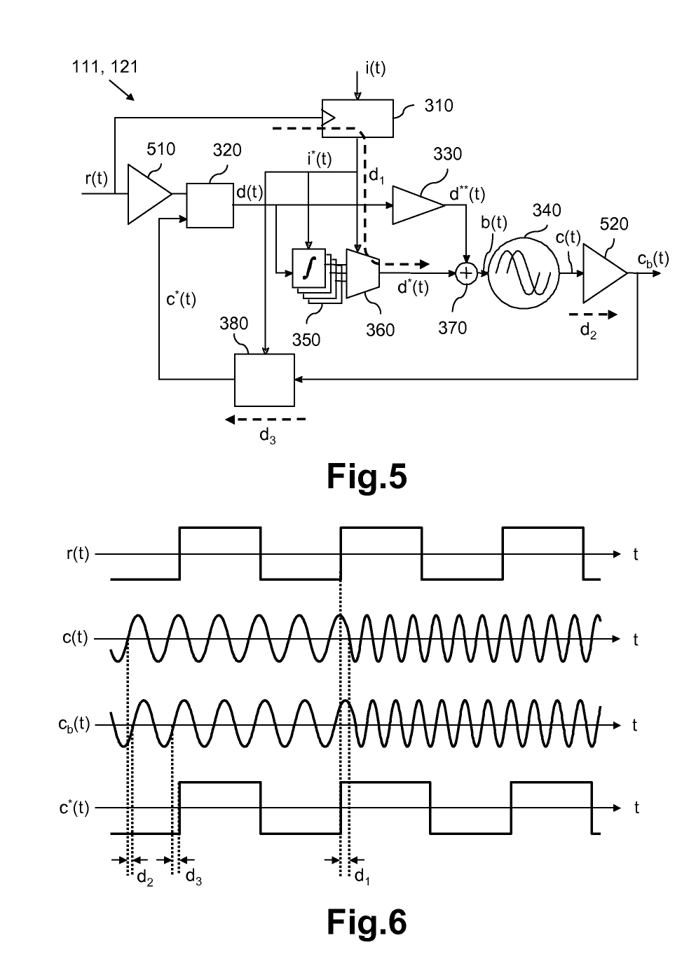

A final further improvement of the present invention is shown in FIGS. 5 and 6. This improvement is based on the thought, that the effect of the instruction signal i(t) provided at to the clockable register 310 would be delayed by a first delay d₁ at the clockable register 310, by a second delay d₂ at an optional buffer 520 buffering the carrier signal c(t) prior outputting and by a third delay d₃ at the optional frequency divider 380. This delay may lead to a loss of phase-synchronization between the normalized carrier signal c^{*}(t) and the reference signal r(t). In other words, the phase difference d(t) deviates from zero and introduces accidental signal components into the phase locked loop. Thus, the settling time and therewith the guard time t_{g} of the phase-locked loop increases.

To avoid the loss of the phase synchronization between the normalized carrier signal c^{*}(t) and the reference signal r(t), it is proposed to further include a delay element 510, which delays the reference signal r(t) prior providing to the phase detector 320. The delay of the delay element 510 should be the sum of all signal delays d₁, d₂, d₃ in the phase-locked loop.

The present invention basically proposes a control loop in which the operational state of the correction element is stored after the operation and read out as initial state prior the operation. This immediately transfers the correction element into the operational state and reduces the settling time of the control loop. In an improved control loop, it is proposed to delay a change of the operational state of the control loop until a predetermined point in time. By that means, the final control state of the control path is known and thus there is no need to fetch this final control state from a memory element prior the operation. In a further improved control loop, it is proposed to measure the delay between instructing a change of the operational state of the control loop and the effect of the instruction and to also delay the command value of the control loop with the measured delay. This keeps the output signal and the command value in phase to each other and further reduces the settling time.

1. Control loop for receiving a reference signal and generating an output signal based on the reference signal comprising:
a subtracting element for generating a difference signal d(t) including a difference between the reference signal and the output signal;
a correcting element for generating an adjusting signal based on the difference signal;
a control path for generating the output signal based on the adjusting signal; and
a storage element for storing at least one internal state at least of the correcting element and for applying the stored internal state at least to the correcting element based on an instruction signal.

2. Control loop according to claim 1, wherein the control path is a controllable oscillator.

3. Control loop according to claim 1, wherein the subtracting element is a phase detector adapted to detect a phase difference between the reference signal and the output signal.

4. Control loop according to claim 1, wherein the correcting element includes at least a first integrator adapted to integrate the difference signal.

5. Control loop according to claim 4, wherein the correcting element includes at least a second integrator adapted to integrate the difference signal, wherein the operation of the first and the second integrators is selected based on the instruction signal.

6. Control loop according to claim 5, wherein the storage element is
the first and second integrator, each storing its operational state after finishing its operation.

7. Control loop according to claim 4, wherein the storage element includes at least a first memory element and a second memory element for
respectively storing one of the internal state of the first integrator or and the internal state of the second integrator, or
respectively providing the stored internal state to the first integrator or the second integrator based on the instruction signal.

8. Control loop according to claim 4, wherein the correcting element includes a proportional gain element for amplifying the difference signal, wherein the adjusting signal is generated by summing the output of at least one of the integrators and the proportional gain element.

9. Control loop according to claim 1, further comprising at least one of:
a first frequency divider, for reducing a frequency of the output signal prior providing to the subtracting element based on the instruction signal and
a second frequency divider, for reducing a frequency of the reference signal prior providing to the subtracting element based on the instruction signal.

10. Control loop according to claim 1, further comprising a clockable register for delaying the instruction signal based on the reference signal.

11. Control loop according to claim 10, wherein the instruction signal is outputted based a positive zero crossing of the reference signal.

12. Control loop according to claim 10, further comprising a delay element for delaying the reference signal prior supplying to the subtracting element based on at least the signal delay occurring due to the clockable register.

13. Signal generator including a control loop according to claim 1, wherein the reference signal is optionally a periodic signal for setting an output signal with a predetermined frequency.

14. Frequency hopping transmitter for transmitting a transmission signal including an information signal, the transmitter comprising,
a signal generator according to claim 13 for generating one of a predetermined number of carrier signals based on a frequency signal;
a signal mixer for generating the transmission signal by mixing the carrier signal with the information signal; and
an antenna for transmitting the transmission signal.

15. Method for generating an output signal with a control loop including a subtracting element for generating a difference signal including a difference between the reference signal and the output signal, a correcting element for generating an adjusting signal based on the difference signal and a control path for generating the output signal based on the adjusting signal, wherein the method comprises:
storing an internal state of at least the correcting element; and
applying the stored internal state at least to the correcting element based on receiving an instruction signal.
